(19) United States
(12) Patent Application Publication
(10) Pub. No.: US 2024/0110996 A1
(43) Pub. Date: Apr. 4, 2024

(54) SYSTEM AND METHOD FOR PREDICTION ANALYSIS OF A SYSTEM UTILIZING MACHINE LEARNING NETWORKS

(71) Applicant: Robert Bosch GmbH, Stuttgart (DE)

(72) Inventors: Ivan BATALOV, Pittsburgh, PA (US); Filipe J. CABRITA CONDESSA, Pittsburgh, PA (US)

(21) Appl. No.: 17/957,574

(22) Filed: Sep. 30, 2022

(51) Int. Cl. G01R 31/50; G06F 17/14; G06N 3/04

(52) U.S. Cl. CPC G01R 31/50; G06F 17/14; G06N 3/0481

(57) ABSTRACT

A computer-implemented method includes receiving a combination recorded signals indicating current, voltage, vibrational, and sound information associated with a test device, generating a training data set utilizing the signals, wherein the training data set is sent to a machine learning model, and in response to meeting a convergence threshold of the machine learning model, outputting a trained model that outputs a prediction using the recorded signals from the combination. The prediction indicates a predicted signal characteristic. The method also includes comparing the prediction and signal associated with the test device to identify a prediction error associated with the device, and outputting a prediction analysis indicating information associated with at least the prediction error. The prediction analysis includes information indicative of a relationship between the device and its signals.

### TECHNICAL FIELD

The present disclosure relates to a machine learning network, including a machine learning network associated with a device with an electric drive machine.

### BACKGROUND

In the process of product analysis and development, a common and central task is the determination of the relationship between different structural and functional properties of the product. For example, when optimizing product's design to improve its noise-vibration-harshness (NVH) characteristics, it is important to know how the sound that reaches the customer is dependent upon the vibrations of the product's various internal components (e.g. an electric drive). Knowing these dependencies can inform and guide product designers and engineers about which components need to be modified in order to improve product's characteristics and how to achieve such an improvement.

No standard technique exists that allows a system to detect and analyze these types of relationships and most modern approaches rely on physics-driven models that are custom developed for individual applications, often from scratch. Neural networks have been used in the past to estimate mutual information between different quantities, however, these approaches have not been applied to the domain of product development and they are limited to only estimating the mutual information itself, which may not always be the desired metric.

### SUMMARY

According to a first embodiment, a computer-implemented method including receiving a combination of two or more recorded signals indicating current information, voltage information, vibrational information, and sound information associated with a test device, generating a training data set utilizing at least current information, voltage information, vibrational information, and sound information, wherein the training data set is fed into a machine learning model, in response to meeting a convergence threshold of the machine learning model, outputting a trained machine learning model, outputting a prediction utilizing the trained machine learning model and at least one recorded signal from the combination, wherein the prediction indicates a predicted signal characteristic associated with one of the two or more signals associated with the test device, comparing the prediction and one of the two or more signals associated with the test device to identify a prediction error associated with the test device, and outputting a prediction analysis indicating information associated with at least the prediction error, wherein the prediction analysis includes information indicative of a relationship between both the two or more recorded signals indicating current information, voltage information, vibrational information, and sound information and one or more of a sound, torque, or vibration emitted or absent from the test device in operation.

According to a second embodiment, a computer-implemented method includes receiving a combination of two or more input signals indicating current information, voltage information, vibrational information, and sound information associated with a test device in a test environment; generating a training data set utilizing at least current information, voltage information, vibrational information and sound information, wherein the training data set is fed into a machine learning model; in response to meeting a convergence threshold of the machine learning model, outputting a trained machine learning model; outputting a prediction utilizing the trained machine learning model and the combination, wherein the prediction indicates a signal characteristic prediction associated with the test device; processing the prediction to obtain a post-processed prediction; and in response to a comparison of the post-processed prediction and a prediction error, outputting a prediction analysis including information associated with the prediction, wherein the prediction analysis includes information indicative of a relationship between both one of the two or more recorded signals indicating current information, voltage information, vibrational information, and sound information and one or more of a sound, torque, or vibration emitted or absent from the test device in operation.

According to a third embodiment, a system includes a processor in communication with one or more sensors. The processor is programmed to receive a combination of two or more recorded signals indicating current information, voltage information, vibrational information, and sound information associated with a test device, generate a training data set utilizing at least current information, voltage information, vibrational information and sound information, wherein the training data set is fed into a machine learning model in response to meeting a convergence threshold of the machine learning model, output a trained machine learning model, output a prediction utilizing the trained machine learning model and at least one input information from the combination, wherein the prediction indicates a predicted signal characteristic associated one of the two or more recorded signals associated with the test device, comparing the prediction to an associated recorded signal of the test device to identify a prediction error, and output a prediction analysis indicating information associated with the prediction and the prediction error, wherein the prediction analysis includes information indicative of a relationship between both one of the two or more recorded signals indicating current information, voltage information, vibrational information, and sound information and one or more of a sound, torque, or vibration emitted or absent from the test device in operation.

### BRIEF DESCRIPTION OF THE DRAWINGS

FIG. 1 shows a system 100 for training a neural network.

FIG. 2 depicts a data annotation system 200 to implement a system for annotating data.

FIG. 3 discloses a flow chart of an embodiment utilizing sound information to train a machine learning model.

FIG. 4A discloses is a flow chart utilizing a direct prediction.

FIG. 4B discloses is a flow chart utilizing an indirect prediction.

FIG. 5 depicts a schematic diagram of an interaction between computer-controlled machine 10 and control system 12.

FIG. 6 depicts a schematic diagram of the control system configured to control a vehicle, which may be a partially autonomous vehicle or a partially autonomous robot.

FIG. 7 depicts a schematic diagram of the control system configured to control a manufacturing machine, such as a punch cutter, a cutter or a gun drill, of manufacturing system, such as part of a production line.

FIG. 8 depicts a schematic diagram of the control system configured to control a power tool, such as a power drill or driver, that has an at least partially autonomous mode.

FIG. 9 depicts a schematic diagram of the control system configured to control an automated personal assistant.

FIG. 10 discloses an example of a virtual sensing model flow chart in one scenario.

FIG. 11 discloses a chart of a system monitoring end of line testing as related to various sensor data to output a prediction, which may include a torque prediction or sound prediction.

FIG. 12 discloses a flow chart associated with a prediction analysis model.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

The proposed method may rely on the analysis of the target prediction error, which can be done in a variety of ways, and therefore is a versatile approach and relatively easily applied to improve and guide product development and analysis. The system and method propose a method for analyzing the relationship between different sensor signals of properties of a physical system by analyzing the performance of neural networks trained to predict the target quantities using the source quantities as an input. This method has a number of advantages over the existing approaches that involve developing a physics-based model or directly estimating mutual information using neural networks.

The system and method may be purely data-driven, in one embodiment, and may not require deep domain knowledge for each individual task. Furthermore, it may be easily applied to different systems and different signals or properties of the studied system. Due to the representational power of neural networks, this method can model complex system-specific non-linear relationships that would be difficult to develop using physics-based models. The prediction error analysis can be altered depending on the task at hand to achieve the desired result, making this approach more versatile than directly estimating the mutual information between the source and the target signal.

During the analysis of a complex physical system, such as a next-generation prototype of a multi-component product, it is often extremely difficult to determine how the product's various functional properties are related to its design parameters, including specific structural and functional properties of the product's components, due to the complex nature of such relationships. One measure of the “strength” of such relationship between two physical quantities S (source) and T (target) is mutual information:

I(S,T)=H(T)−H(T|S)=D_{KL}(p(S,T)∥p(S)*p(T))>0
where H(T) is the entropy of the target, H(T|S) is the entropy of the target conditioned on the source, and D_{KL} (p(S,T)∥p(S)*p(T)) is the Kullback-Leibler divergence between the joint distribution and the product of marginal distributions of S and T. I(S,T)=0 indicates that measuring S does not reduce the uncertainty of T, i.e. H(T)=H(T|S). I(S,T)=1 T can be determined with 100% confidence given S, i.e. H(T|S)=0.

However, estimating mutual information in real systems is challenging using classical methods as both S and T can be high-dimensional continuous variables (e.g. in case of time series signals such as sound, ultrasound, radar or Lidar, or even images or video sequences). Previous studies have shown that neural networks can be used to directly estimate mutual information between random variables, which is possible due to their ability to model a wide range of complex non-linear relationships. However, getting a direct estimate of mutual information, is often not the desired goal during system analysis. A more useful measure for the product engineers is the expected value of the target quantity given the input quantity, which is dependent upon the mutual information and can also be estimated using neural networks: f(S)=E(T|S). When I(S,T)=1, H(T|S)=0 and E(T|S)=T, i.e. the prediction error is zero. When I(S,T)=0, H(T|S)=H(T), and E(T|S)=E(T), e.g. the prediction is the expected value of the target, which in the context of neural networks equals to the mean target value over the observed data. Therefore, by observing the neural network prediction error, one can detect and analyze the relationship between the source and the target. Additionally, the predicted signal doesn't have to be compared to the target one in its raw form, post-processing can be used to derive various properties of the target signal for comparison (e.g., a Fourier transform, sound loudness, roughness, or harshness calculation, calculating an amplitude of a certain order, etc.), which makes such analysis significantly more versatile.

The proposed method is intended for use during the analysis of complex physical systems, such as multi-component manufactured products. Firstly, the quantities relationship between which needs to be investigated are chosen. For example, the vibrations of the electric motor operating window lifters in a car and the sound inside the cabin. Secondly, the chosen quantities are measured in the appropriate setting, e.g., in the way that allows for the hypothesized relationship between measured quantities to be determined. In the above example, that would imply recording both the accelerometer and the microphone data at the same time in the same vehicle. Thirdly, a neural network is trained to predict one of the quantities using the other, e.g. a signal-to-signal model that takes the accelerometer time series as an input and predicts sound time series. And finally, the performance of the network is analyzed to determine the presence/absence of the relationship and its properties. In the above example, the prediction error can be analyzed in the time domain to estimate the mutual information between motor vibrations and the sound inside the cabin, and in the frequency domain to determine which sound frequencies arise from motor vibrations. For the latter, a Fourier transform is applied to both the predicted and the recorded signal to obtain the frequency information and the error is calculated between the resulting Fourier coefficients.

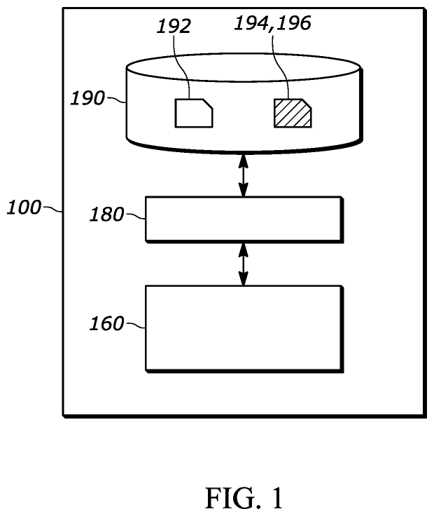

FIG. 1 shows a system 100 for training a neural network. The system 100 may comprise an input interface for accessing training data 192 for the neural network. For example, as illustrated in FIG. 1, the input interface may be constituted by a data storage interface 180 which may access the training data 192 from a data storage 190. For example, the data storage interface 180 may be a memory interface or a persistent storage interface, e.g., a hard disk or an SSD interface, but also a personal, local or wide area network interface such as a Bluetooth, Zigbee or Wi-Fi interface or an ethernet or fiberoptic interface. The data storage 190 may be an internal data storage of the system 100, such as a hard drive or SSD, but also an external data storage, e.g., a network-accessible data storage.

In some embodiments, the data storage 190 may further comprise a data representation 194 of an untrained version of the neural network which may be accessed by the system 100 from the data storage 190. It will be appreciated, however, that the training data 192 and the data representation 194 of the untrained neural network may also each be accessed from a different data storage, e.g., via a different subsystem of the data storage interface 180. Each subsystem may be of a type as is described above for the data storage interface 180. In other embodiments, the data representation 194 of the untrained neural network may be internally generated by the system 100 on the basis of design parameters for the neural network, and therefore may not explicitly be stored on the data storage 190. The system 100 may further comprise a processor subsystem 160 which may be configured to, during operation of the system 100, provide an iterative function as a substitute for a stack of layers of the neural network to be trained. In one embodiment, respective layers of the stack of layers being substituted may have mutually shared weights and may receive, as input, an output of a previous layer, or for a first layer of the stack of layers, an initial activation, and a part of the input of the stack of layers. The system may also include multiple layers. The processor subsystem 160 may be further configured to iteratively train the neural network using the training data 192. Here, an iteration of the training by the processor subsystem 160 may comprise a forward propagation part and a backward propagation part. The processor subsystem 160 may be configured to perform the forward propagation part by, amongst other operations defining the forward propagation part which may be performed, determining an equilibrium point of the iterative function at which the iterative function converges to a fixed point, wherein determining the equilibrium point comprises using a numerical root-finding algorithm to find a root solution for the iterative function minus its input, and by providing the equilibrium point as a substitute for an output of the stack of layers in the neural network. The system 100 may further comprise an output interface for outputting a data representation 196 of the trained neural network, this data may also be referred to as trained model data 196. For example, as also illustrated in FIG. 1, the output interface may be constituted by the data storage interface 180, with said interface being in these embodiments an input/output (“IO”) interface, via which the trained model data 196 may be stored in the data storage 190. For example, the data representation 194 defining the ‘untrained’ neural network may during or after the training be replaced, at least in part by the data representation 196 of the trained neural network, in that the parameters of the neural network, such as weights, hyper parameters and other types of parameters of neural networks, may be adapted to reflect the training on the training data 192. This is also illustrated in FIG. 1 by the reference numerals 194, 196 referring to the same data record on the data storage 190. In other embodiments, the data representation 196 may be stored separately from the data representation 194 defining the ‘untrained’ neural network. In some embodiments, the output interface may be separate from the data storage interface 180, but may in general be of a type as described above for the data storage interface 180.

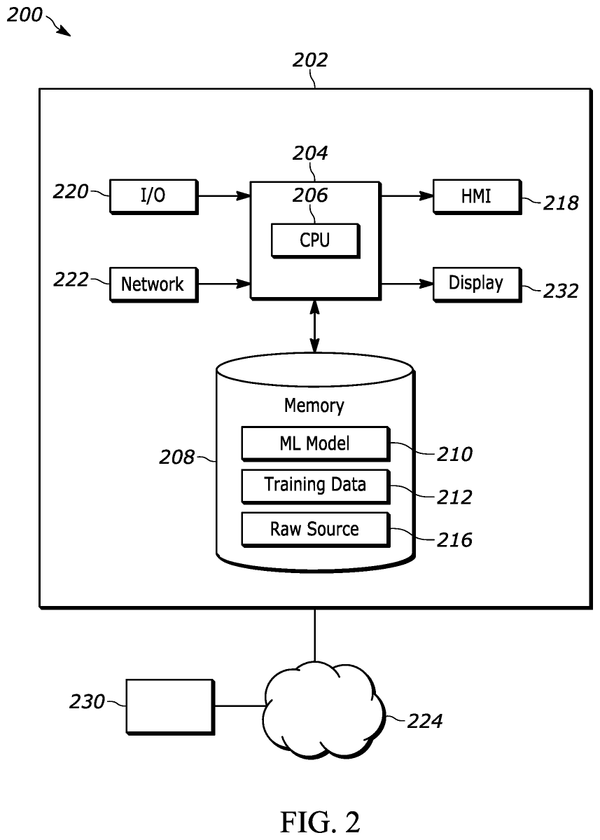

FIG. 2 depicts a data annotation system 200 to implement a system for annotating data. The data annotation system 200 may include at least one computing system 202. The computing system 202 may include at least one processor 204 that is operatively connected to a memory unit 208. The processor 204 may include one or more integrated circuits that implement the functionality of a central processing unit (CPU) 206. The CPU 206 may be a commercially available processing unit that implements an instruction stet such as one of the x86, ARM, Power, or MIPS instruction set families. During operation, the CPU 206 may execute stored program instructions that are retrieved from the memory unit 208. The stored program instructions may include software that controls operation of the CPU 206 to perform the operation described herein. In some examples, the processor 204 may be a system on a chip (SoC) that integrates functionality of the CPU 206, the memory unit 208, a network interface, and input/output interfaces into a single integrated device. The computing system 202 may implement an operating system for managing various aspects of the operation.

The memory unit 208 may include volatile memory and non-volatile memory for storing instructions and data. The non-volatile memory may include solid-state memories, such as NAND flash memory, magnetic and optical storage media, or any other suitable data storage device that retains data when the computing system 202 is deactivated or loses electrical power. The volatile memory may include static and dynamic random-access memory (RAM) that stores program instructions and data. For example, the memory unit 208 may store a machine-learning model 210 or algorithm, a training dataset 212 for the machine-learning model 210, raw source dataset 215.

The computing system 202 may include a network interface device 222 that is configured to provide communication with external systems and devices. For example, the network interface device 222 may include a wired and/or wireless Ethernet interface as defined by Institute of Electrical and Electronics Engineers (IEEE) 802.11 family of standards. The network interface device 222 may include a cellular communication interface for communicating with a cellular network (e.g., 3G, 4G, 5G). The network interface device 222 may be further configured to provide a communication interface to an external network 224 or cloud.

The external network 224 may be referred to as the world-wide web or the Internet. The external network 224 may establish a standard communication protocol between computing devices. The external network 224 may allow information and data to be easily exchanged between computing devices and networks. One or more servers 230 may be in communication with the external network 224.

The computing system 202 may include an input/output (I/O) interface 220 that may be configured to provide digital and/or analog inputs and outputs. The I/O interface 220 may include additional serial interfaces for communicating with external devices (e.g., Universal Serial Bus (USB) interface).

The computing system 202 may include a human-machine interface (HMI) device 218 that may include any device that enables the system 200 to receive control input. Examples of input devices may include human interface inputs such as keyboards, mice, touchscreens, voice input devices, and other similar devices. The computing system 202 may include a display device 232. The computing system 202 may include hardware and software for outputting graphics and text information to the display device 232. The display device 232 may include an electronic display screen, projector, printer or other suitable device for displaying information to a user or operator. The computing system 202 may be further configured to allow interaction with remote HMI and remote display devices via the network interface device 222.

The system 200 may be implemented using one or multiple computing systems. While the example depicts a single computing system 202 that implements all of the described features, it is intended that various features and functions may be separated and implemented by multiple computing units in communication with one another. The particular system architecture selected may depend on a variety of factors.

The system 200 may implement a machine-learning algorithm 210 that is configured to analyze the raw source dataset 215. The raw source dataset 215 may include raw or unprocessed sensor data that may be representative of an input dataset for a machine-learning system. The raw source dataset 215 may include video, video segments, images, text-based information, and raw or partially processed sensor data (e.g., radar map of objects). In some examples, the machine-learning algorithm 210 may be a neural network algorithm that is designed to perform a predetermined function. For example, the neural network algorithm may be configured in automotive applications to identify pedestrians in video images.

The computer system 200 may store a training dataset 212 for the machine-learning algorithm 210. The training dataset 212 may represent a set of previously constructed data for training the machine-learning algorithm 210. The training dataset 212 may be used by the machine-learning algorithm 210 to learn weighting factors associated with a neural network algorithm. The training dataset 212 may include a set of source data that has corresponding outcomes or results that the machine-learning algorithm 210 tries to duplicate via the learning process. In this example, the training dataset 212 may include source videos with and without pedestrians and corresponding presence and location information. The source videos may include various scenarios in which pedestrians are identified.

The machine-learning algorithm 210 may be operated in a learning mode using the training dataset 212 as input. The machine-learning algorithm 210 may be executed over a number of iterations using the data from the training dataset 212. With each iteration, the machine-learning algorithm 210 may update internal weighting factors based on the achieved results. For example, the machine-learning algorithm 210 can compare output results (e.g., annotations) with those included in the training dataset 212. Since the training dataset 212 includes the expected results, the machine-learning algorithm 210 can determine when performance is acceptable. After the machine-learning algorithm 210 achieves a predetermined performance level (e.g., 100% agreement with the outcomes associated with the training dataset 212), the machine-learning algorithm 210 may be executed using data that is not in the training dataset 212. The trained machine-learning algorithm 210 may be applied to new datasets to generate annotated data.

The machine-learning algorithm 210 may be configured to identify a particular feature in the raw source data 215. The raw source data 215 may include a plurality of instances or input dataset for which annotation results are desired. For example, the machine-learning algorithm 210 may be configured to identify the presence of a pedestrian in video images and annotate the occurrences. The machine-learning algorithm 210 may be programmed to process the raw source data 215 to identify the presence of the particular features. The machine-learning algorithm 210 may be configured to identify a feature in the raw source data 215 as a predetermined feature (e.g., pedestrian). The raw source data 215 may be derived from a variety of sources. For example, the raw source data 215 may be actual input data collected by a machine-learning system. The raw source data 215 may be machine generated for testing the system. As an example, the raw source data 215 may include raw video images from a camera.

In the example, the machine-learning algorithm 210 may process raw source data 215 and output an indication of a representation of an image. The output may also include augmented representation of the image. A machine-learning algorithm 210 may generate a confidence level or factor for each output generated. For example, a confidence value that exceeds a predetermined high-confidence threshold may indicate that the machine-learning algorithm 210 is confident that the identified feature corresponds to the particular feature. A confidence value that is less than a low-confidence threshold may indicate that the machine-learning algorithm 210 has some uncertainty that the particular feature is present.

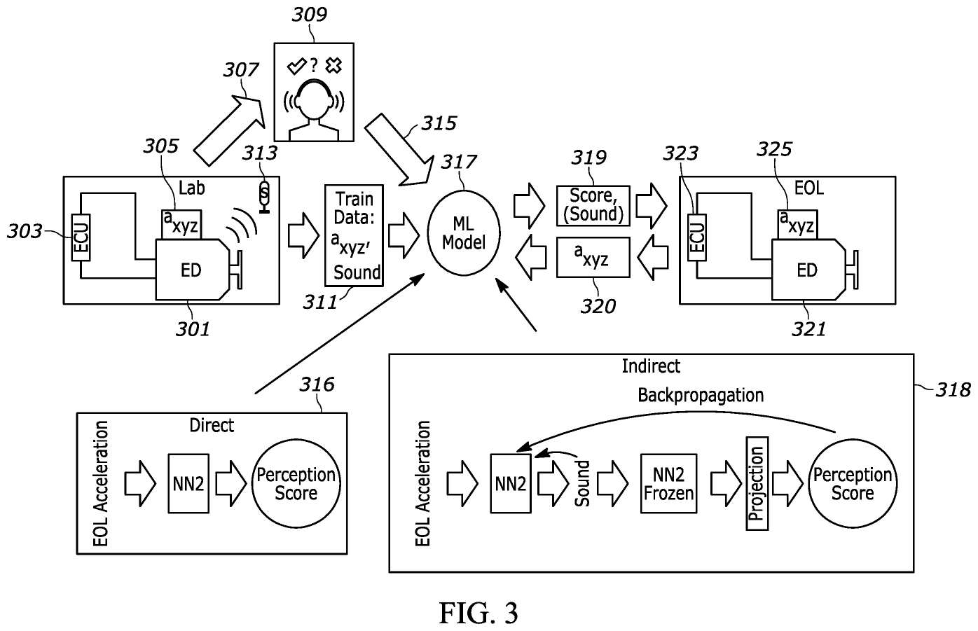

FIG. 3 discloses a flow chart of an embodiment utilizing sound information to train a machine learning model. The electronic device may be any type of device. For example, the electronic device may be a vehicle, power tool, or any type of device that emits a sound from an electric drives. The electrical drive may be either an ACT motor drive or DC motor drive in one embodiment. For example, an AC drive may be a device used to control the speed of an electric motor such as a three-phase induction motor by changing the frequency of the electrical supply to the motor. The AC drive may also called Variable Frequency Drive (VFD) or Variable Speed Drive (VSD). The DC motor drive may be a speed control system of a DC electrical motor that supplies voltage to the motor to operate at desired speed. DC drives may also be classified as analog DC drives and digital DC drives.

The electrical drive 301 may include one or more sensors that emit sound. The electrical drive 301 may include a processor, controller, or electronic control unit 303. For example, the sensor may include an accelerometer 305. The sound 307 may be emitted from the electrical drive (EDs) and picked up by a microphone 313. To train the data, the sound may be emitted in a laboratory setting and utilized. Thus, training data may 311 be utilized form a lab setting. The laboratory may include a noise-free environment with a microphone 313 to retrieve the sound. With the training data 311, human perception scores from the microphone data may be estimated utilizing a score prediction network.

The sound information 307 may be manually determined 309 by a human to derive a score 315 in one aspect. For example, the human or humans may hear the sound information associated with various settings of the electrical device and attribute a perception score to it. The perception score may also be automatically programmed in other embodiments. For example, the system may utilize various characteristics of the sounds (e.g., decibel level, sound frequency, prevalence of uncharacteristic sounds, etc.) to attribute a sound perception score 319. A hybrid approach utilizing both may be utilized. However, the scores may be fed into the machine learning model which may be utilized to train sound from other testing.

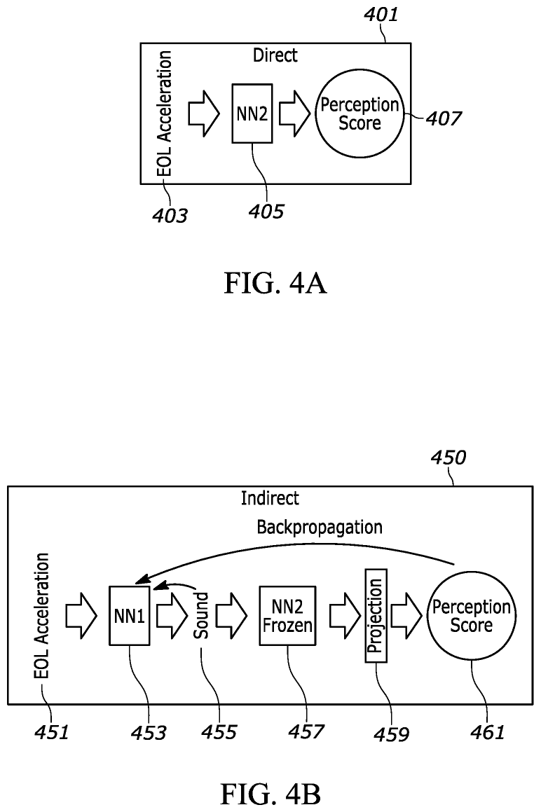

The machine learning network may utilize the training data to train the machine learning network to identify the sound emitted from the EDs. The training data may include at least the accelerometer data utilized in it. The accelerometer data may include multiple axis information, including x-axis, y-axis, and z-axis information. The machine learning model may train the model utilizing a direct method or an indirect method. The direct method and indirect method are discussed in more detail in FIG. 4A. and FIG. 4B below, respectively. In some embodiments, a combination of both methods may be utilized to train the machine learning model.

Next, the system may then operate at an end of line testing environment. Due the EOL environment being noisy, the sound information may be not be available. The system may utilize the real-time vibrational (e.g. accelerometer) data in the EOL environment. Thus, even when sound information is not available in certain environments, the trained machine learning model may relay on the vibrational data from the device to identify a perception score as pertaining to the sound of the various components of the device. The system may then output a perception score associated with the EOL device utilizing the vibrational data. Based on the perception score, the system may determine whether the

The method described above will eliminate the need to evaluate human perception scores utilizing jury testing. Furthermore, less data may be needed as compared to a usual model.

FIG. 4A discloses a flow chart utilizing a direct prediction 401. The direct prediction method 401 may be utilized to train the machine learning model. The machine learning model may be trained upon a convergence threshold. The machine learning model network may be trained to output or predict human perception score 407 directly from the accelerometer data 403 by minimizing the score prediction error. The accelerometer data 403 may be obtained from the end-of-line testing or any other type of environment and fed into a neural network 405. Thus, upon hitting a threshold of a certain score prediction error, the system may output a trained model. The trained model may be deployed to an end-of-line environment or any other type of environment setting.

FIG. 4B discloses a flow chart utilizing indirect prediction 450. The indirect method may include one or more neural networks 453, 457. The neural network 453 may be trained to predict a measured sound from the accelerometer data. Another neural network 457 may be trained to predict a human perception score 461 from sound information/data. The second neural network 457 may output a projection 459 associated with the sound. The projection 459 may be utilized to identify a perception score 461. The predicted sound 461 may be sent into a score prediction network. The score prediction network may generate a human perception score from the sample. The human perception score 461 may be reflective of various characteristics of the sound 455, such as weather the sound is pleasant, unpleasant, high-pitched, low-pitched, etc, or not. During the training of the sound prediction network, the weights of the score prediction network may be frozen, and the weights of the sound prediction network are trained to minimize a weighted sum of sound and score prediction errors. Upon approaching or reaching a convergence threshold, the system may output a trained network and the trained network may be deployed.

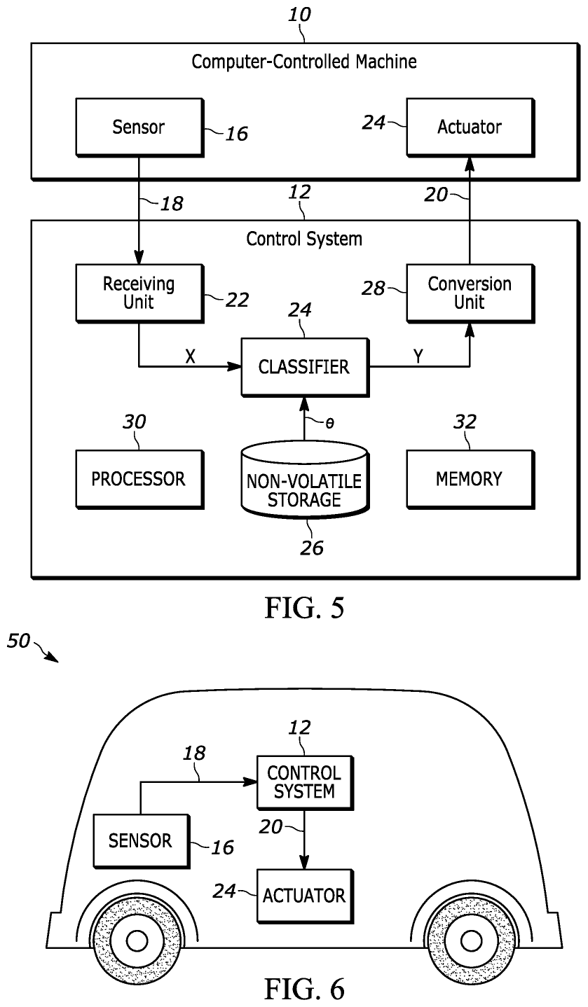

FIG. 5 depicts a schematic diagram of an interaction between computer-controlled machine 10 and control system 12. The computer-controlled machine 10 may include a neural network as described above, such as a network that includes a score prediction network. The computer-controlled machine 10 includes actuator 14 and sensor 16. Actuator 14 may include one or more actuators and sensor 16 may include one or more sensors. Sensor 16 is configured to sense a condition of computer-controlled machine 10. Sensor 16 may be configured to encode the sensed condition into sensor signals 18 and to transmit sensor signals 18 to control system 12. Non-limiting examples of sensor 16 include video, radar, LiDAR, ultrasonic and motion sensors. In one embodiment, sensor 16 is an optical sensor configured to sense optical images of an environment proximate to computer-controlled machine 10.

Control system 12 is configured to receive sensor signals 18 from computer-controlled machine 10. As set forth below, control system 12 may be further configured to compute actuator control commands 20 depending on the sensor signals and to transmit actuator control commands 20 to actuator 14 of computer-controlled machine 10.

As shown in FIG. 5, control system 12 includes receiving unit 22. Receiving unit 22 may be configured to receive sensor signals 18 from sensor 16 and to transform sensor signals 18 into input signals x. In an alternative embodiment, sensor signals 18 are received directly as input signals x without receiving unit 22. Each input signal x may be a portion of each sensor signal 18. Receiving unit 22 may be configured to process each sensor signal 18 to product each input signal x. Input signal x may include data corresponding to an image recorded by sensor 16.

Control system 12 includes classifier 24. Classifier 24 may be configured to classify input signals x into one or more labels using a machine learning (ML) algorithm, such as a neural network described above. The input signal x may include sound information. Classifier 24 is configured to be parametrized by parameters, such as those described above (e.g., parameter θ). Parameters θ may be stored in and provided by non-volatile storage 26. Classifier 24 is configured to determine output signals y from input signals x. Each output signal y includes information that assigns one or more labels to each input signal x. Classifier 24 may transmit output signals y to conversion unit 28. Conversion unit 28 is configured to covert output signals y into actuator control commands 20. Control system 12 is configured to transmit actuator control commands 20 to actuator 14, which is configured to actuate computer-controlled machine 10 in response to actuator control commands 20. In another embodiment, actuator 14 is configured to actuate computer-controlled machine 10 based directly on output signals y.

Upon receipt of actuator control commands 20 by actuator 14, actuator 14 is configured to execute an action corresponding to the related actuator control command 20. Actuator 14 may include a control logic configured to transform actuator control commands 20 into a second actuator control command, which is utilized to control actuator 14. In one or more embodiments, actuator control commands 20 may be utilized to control a display instead of or in addition to an actuator.

In another embodiment, control system 12 includes sensor 16 instead of or in addition to computer-controlled machine 10 including sensor 16. Control system 12 may also include actuator 14 instead of or in addition to computer-controlled machine 10 including actuator 14.

As shown in FIG. 5, control system 12 also includes processor 30 and memory 32. Processor 30 may include one or more processors. Memory 32 may include one or more memory devices. The classifier 24 (e.g., ML algorithms) of one or more embodiments may be implemented by control system 12, which includes non-volatile storage 26, processor 30 and memory 32.

Non-volatile storage 26 may include one or more persistent data storage devices such as a hard drive, optical drive, tape drive, non-volatile solid-state device, cloud storage or any other device capable of persistently storing information. Processor 30 may include one or more devices selected from high-performance computing (HPC) systems including high-performance cores, microprocessors, micro-controllers, digital signal processors, microcomputers, central processing units, field programmable gate arrays, programmable logic devices, state machines, logic circuits, analog circuits, digital circuits, or any other devices that manipulate signals (analog or digital) based on computer-executable instructions residing in memory 32. Memory 32 may include a single memory device or a number of memory devices including, but not limited to, random access memory (RAM), volatile memory, non-volatile memory, static random access memory (SRAM), dynamic random access memory (DRAM), flash memory, cache memory, or any other device capable of storing information.

Processor 30 may be configured to read into memory 32 and execute computer-executable instructions residing in non-volatile storage 26 and embodying one or more ML algorithms and/or methodologies of one or more embodiments. Non-volatile storage 26 may include one or more operating systems and applications. Non-volatile storage 26 may store compiled and/or interpreted from computer programs created using a variety of programming languages and/or technologies, including, without limitation, and either alone or in combination, Java, C, C++, C#, Objective C, Fortran, Pascal, Java Script, Python, Perl, and PL/SQL.

Upon execution by processor 30, the computer-executable instructions of non-volatile storage 26 may cause control system 12 to implement one or more of the ML algorithms and/or methodologies as disclosed herein. Non-volatile storage 26 may also include ML data (including data parameters) supporting the functions, features, and processes of the one or more embodiments described herein.

The program code embodying the algorithms and/or methodologies described herein is capable of being individually or collectively distributed as a program product in a variety of different forms. The program code may be distributed using a computer readable storage medium having computer readable program instructions thereon for causing a processor to carry out aspects of one or more embodiments. Computer readable storage media, which is inherently non-transitory, may include volatile and non-volatile, and removable and non-removable tangible media implemented in any method or technology for storage of information, such as computer-readable instructions, data structures, program modules, or other data. Computer readable storage media may further include RAM, ROM, erasable programmable read-only memory (EPROM), electrically erasable programmable read-only memory (EEPROM), flash memory or other solid state memory technology, portable compact disc read-only memory (CD-ROM), or other optical storage, magnetic cassettes, magnetic tape, magnetic disk storage or other magnetic storage devices, or any other medium that can be used to store the desired information and which can be read by a computer. Computer readable program instructions may be downloaded to a computer, another type of programmable data processing apparatus, or another device from a computer readable storage medium or to an external computer or external storage device via a network.

Computer readable program instructions stored in a computer readable medium may be used to direct a computer, other types of programmable data processing apparatus, or other devices to function in a particular manner, such that the instructions stored in the computer readable medium produce an article of manufacture including instructions that implement the functions, acts, and/or operations specified in the flowcharts or diagrams. In certain alternative embodiments, the functions, acts, and/or operations specified in the flowcharts and diagrams may be re-ordered, processed serially, and/or processed concurrently consistent with one or more embodiments. Moreover, any of the flowcharts and/or diagrams may include more or fewer nodes or blocks than those illustrated consistent with one or more embodiments. The processes, methods, or algorithms can be embodied in whole or in part using suitable hardware components, such as Application Specific Integrated Circuits (ASICs), Field-Programmable Gate Arrays (FPGAs), state machines, controllers or other hardware components or devices, or a combination of hardware, software and firmware components.

FIG. 6 depicts a schematic diagram of control system 12 configured to control vehicle 50, which may be an at least partially autonomous vehicle or an at least partially autonomous robot. As shown in FIG. 5, vehicle 50 includes actuator 14 and sensor 16. Sensor 16 may include one or more video sensors, radar sensors, ultrasonic sensors, LiDAR sensors, and/or position sensors (e.g. GPS). One or more of the one or more specific sensors may be integrated into vehicle 50. Alternatively or in addition to one or more specific sensors identified above, sensor 16 may include a software module configured to, upon execution, determine a state of actuator 14. One non-limiting example of a software module includes a weather information software module configured to determine a present or future state of the weather proximate vehicle 50 or other location.

Classifier 24 of control system 12 of vehicle 50 may be configured to detect objects in the vicinity of vehicle 50 dependent on input signals x. In such an embodiment, output signal y may include information characterizing the vicinity of objects to vehicle 50. Actuator control command 20 may be determined in accordance with this information. The actuator control command 20 may be used to avoid collisions with the detected objects.

In embodiments where vehicle 50 is an at least partially autonomous vehicle, actuator 14 may be embodied in a brake, a propulsion system, an engine, a drivetrain, or a steering of vehicle 50. Actuator control commands 20 may be determined such that actuator 14 is controlled such that vehicle 50 avoids collisions with detected objects. Detected objects may also be classified according to what classifier 24 deems them most likely to be, such as pedestrians or trees. The actuator control commands 20 may be determined depending on the classification. The control system 12 may utilize the robustifier to help train the network for adversarial conditions, such as during poor lighting conditions or poor weather conditions of the vehicle environment, as well as an attack.

In other embodiments where vehicle 50 is an at least partially autonomous robot, vehicle 50 may be a mobile robot that is configured to carry out one or more functions, such as flying, swimming, diving and stepping. The mobile robot may be an at least partially autonomous lawn mower or an at least partially autonomous cleaning robot. In such embodiments, the actuator control command 20 may be determined such that an electric drive, propulsion unit, steering unit and/or brake unit of the mobile robot may be controlled such that the mobile robot may avoid collisions with identified objects.

In another embodiment, vehicle 50 is an at least partially autonomous robot in the form of a gardening robot. In such embodiment, vehicle 50 may use an optical sensor as sensor 16 to determine a state of plants in an environment proximate vehicle 50. Actuator 14 may be a nozzle configured to spray chemicals. The vehicle 50 may be operate and move based on an electrical drive. Depending on an identified species and/or an identified state of the plants, actuator control command 20 may be determined to cause actuator 14 to spray the plants with a suitable quantity of suitable chemicals.

Vehicle 50 may be an at least partially autonomous robot in the form of a domestic appliance. Non-limiting examples of domestic appliances include a washing machine, a stove, an oven, a microwave, or a dishwasher. In such a vehicle 50, sensor 16 may be an optical sensor configured to detect a state of an object which is to undergo processing by the household appliance. For example, in the case of the domestic appliance being a washing machine, sensor 16 may detect a state of the laundry inside the washing machine. Actuator control command 20 may be determined based on the detected state of the laundry.

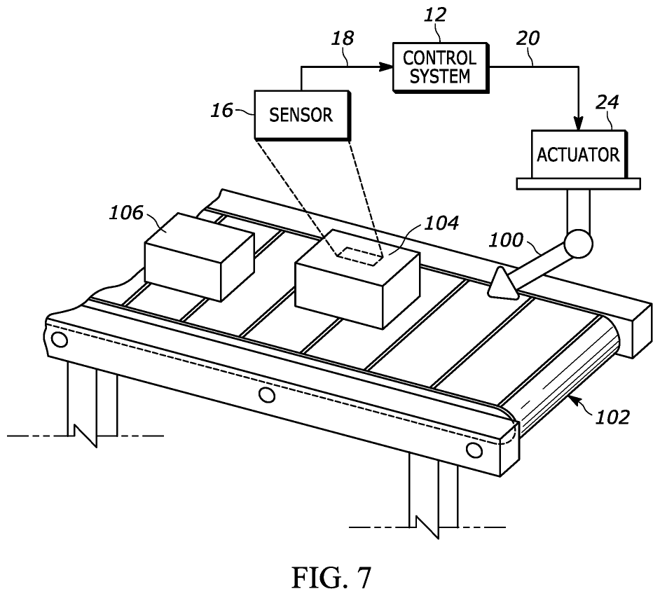

FIG. 7 depicts a schematic diagram of control system 12 configured to control system 100 (e.g., manufacturing machine), such as a punch cutter, a cutter or a gun drill, of manufacturing system 102, such as part of a production line. Control system 12 may be configured to control actuator 14, which is configured to control system 100 (e.g., manufacturing machine).

Sensor 16 of system 100 (e.g., manufacturing machine) may be an optical sensor configured to capture one or more properties of manufactured product 104 or the sensor may be an accelerometer. Classifier 24 may be configured to determine a state of manufactured product 104 from one or more of the captured properties. Actuator 14 may be configured to control system 100 (e.g., manufacturing machine) depending on the determined state of manufactured product 104 for a subsequent manufacturing step of manufactured product 104. The actuator 14 may be configured to control functions of system 100 (e.g., manufacturing machine) on subsequent manufactured product 106 of system 100 (e.g., manufacturing machine) depending on the determined state of manufactured product 104. The control system 12 may utilize the system to help train the machine learning network for adversarial conditions associated with noise utilized by the actuator or an electric drive, such as mechanical failure with parts associated with the production line.

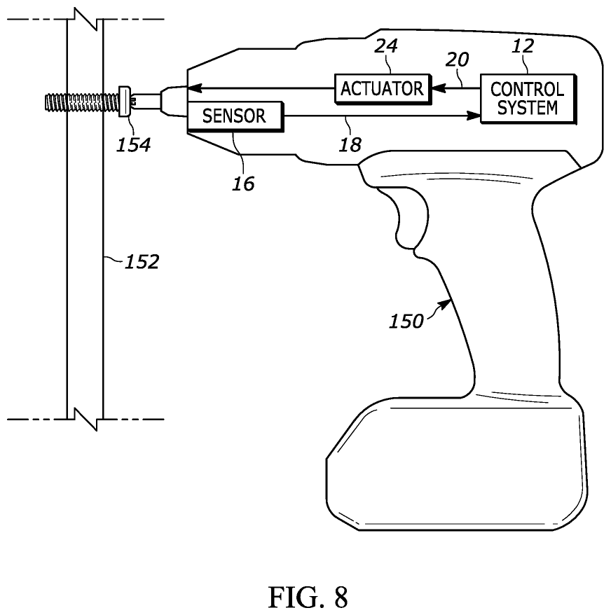

FIG. 8 depicts a schematic diagram of control system 12 configured to control power tool 150, such as a power drill or driver, that has an at least partially autonomous mode. Control system 12 may be configured to control actuator 14, which is configured to control power tool 150. The actuator may be driven by a motor or an electrical drive train. The actuator may emit a sound, as well as the motor or the electrical drive.

Sensor 16 of power tool 150 may be an optical sensor configured to capture one or more properties of work surface 152 and/or fastener 154 being driven into work surface 152. The classifier 24 may be utilized to classify a sound associated with the operation of the tool. Additionally, the classifier 24 may be configured to determine a state of work surface 152 and/or fastener 154 relative to work surface 152 from one or more of the captured properties. The state may be fastener 154 being flush with work surface 152. The state may alternatively be hardness of work surface 152. Actuator 14 may be configured to control power tool 150 such that the driving function of power tool 150 is adjusted depending on the determined state of fastener 154 relative to work surface 152 or one or more captured properties of work surface 152. For example, actuator 14 may discontinue the driving function if the state of fastener 154 is flush relative to work surface 152. As another non-limiting example, actuator 14 may apply additional or less torque depending on the hardness of work surface 152. The control system 12 may utilize the robustifier to help train the machine learning network for adversarial conditions, such as during poor lighting conditions or poor weather conditions. Thus, the control system 12 may be able to identify environment conditions of the power tool 150.

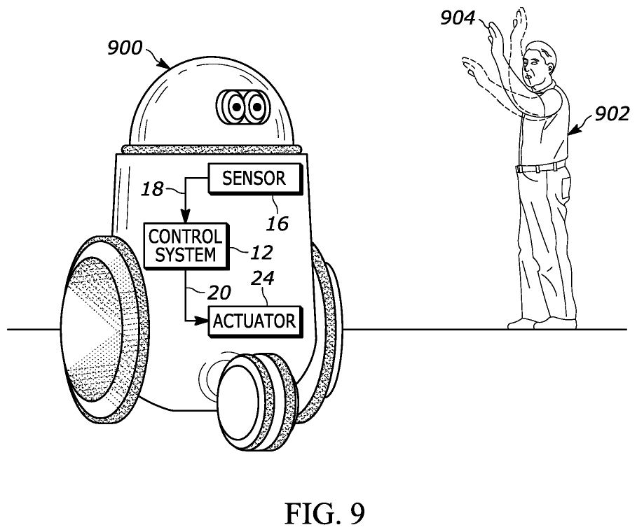

FIG. 9 depicts a schematic diagram of control system 12 configured to control automated personal assistant 900. Control system 12 may be configured to control actuator 14, which is configured to control automated personal assistant 900. Automated personal assistant 900 may be configured to control a domestic appliance, such as a washing machine, a stove, an oven, a microwave or a dishwasher. Sensor 16 may be an optical sensor and/or an audio sensor such as a microphone. The optical sensor may be configured to receive video images of gestures 904 of user 902. The audio sensor may be configured to receive a voice command of user 902.

Control system 12 of automated personal assistant 900 may be configured to determine actuator control commands 20 configured to control system 12. Control system 12 may be configured to determine actuator control commands 20 in accordance with sensor signals 18 of sensor 16. Automated personal assistant 900 is configured to transmit sensor signals 18 to control system 12. Classifier 24 of control system 12 may be configured to execute a gesture recognition algorithm to identify gesture 904 made by user 902, to determine actuator control commands 20, and to transmit the actuator control commands 20 to actuator 14. The actuator may be driven by an electrical drive train machine. Classifier 24 may be configured to sound in response to the drive train activating the actuator and to output the retrieved sound information in a form suitable for reception by user 902. The control system 12 may utilize the classifier to help train the machine learning network for adversarial conditions based on the sound, such as an actuator malfunction or another component malfunction. Thus, the control system 12 may be able to mitigate damage in such a scenario.

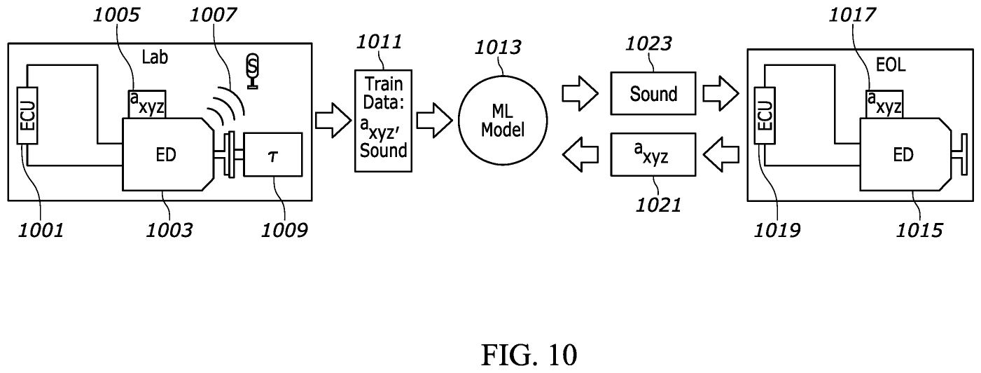

FIG. 10 discloses an example of a virtual sensing model flow chart in one scenario. The system may first be initiated in a laboratory environment or an environment that is noise-free or has relatively low noise (e.g., noise does not impact sound being emitted from the electronic device 1005). For example, the environment may be an anechoic chamber or a laboratory that mitigates any background noise or sound. The system may include an electronic device 1003. The electronic device may include a motor, actuator, electrical drive, propulsion system, or similar component that emits torque 1009. The device 1003 may be in communication with an ECU 1001 that is utilized to process information and data. The electronic device 1003 may include an accelerometer 1005 or another sensor that emits vibrational information, such as accelerometer data being emitted from an actuator or electric drive of a device. Torque 1009 may be emitted by a drive of the device, or any other component. A microphone may obtain the sound 1007 being emitted from the device. The microphone may be located in the laboratory environment or associated with the device 1005.

The sound (e.g., sound information) may be paired with the vibrational data to generate a training data set 1011. The vibrational data may include accelerometer data that includes x-axis, y-axis, and z-axis information. The joint data may be paired to generate a training data set that is fed into a machine learning model 1013. The machine learning model 1013 may be a trained or un-trained model. Thus, if it is an un-trained model, it may be start from the beginning to develop a trained model utilizing the training data 1011 until a convergence threshold is met by reducing a sound prediction error. To the extent the un-trained model is utilized, it may utilize the training data set to create a trained model when a convergence threshold is met and errors are minimized. If the model is already trained or partially trained, the training data may be utilized to improve sound prediction.

Next, an electronic device 1015 may be utilized in a different environment, such as a factory setting or end of line environment. The electrical device 1015 may include one or more ECUs 1019 that is utilized to operate the device or to monitor sensor readings, among other things. The electrical device 1015 may include sensors, such as an accelerometer 1017, that include vibrational information/data or other type of information/data emitted from electrical drive, actuator, or similar component. For example, the vibrational data in the EOL setting may be real-time vibrational information. The environment may not allow accurate use of sound information to be obtained, thus only the vibrational data may suffice to obtain a predicted sound. Notably, a microphone may be missing in such an environment, or the microphone may be difficult to use based on background noise.

The real-time vibrational information 1021 may be sent to the trained machine learning model 1013. In one scenario, the vibrational data may be accelerometer data. The real-time vibrational information 1021 may include accelerometer data that includes x-axis, y-axis, and z-axis information. The real-time data may be sent to the machine learning model 1013 in the form of either time series, spectrogram, or order spectrogram. The form of the input that is fed into the model may be the same as output (e.g. sound prediction 1023) of the model, and thus the input type may dictate the output type. For example, if a spectrogram is utilized as the input of the model, a spectrogram of the same dimensionality is predicted. Thus, the model may utilize the vibrational information to predict a corresponding sound 1023. The sound prediction 1023 may indicate a sound that would be emitted from the device given operation of the device's motor, electrical drive, actuator, or any other component. In one embodiment, this may be accomplished absent any other data and utilizing only the vibrational data.

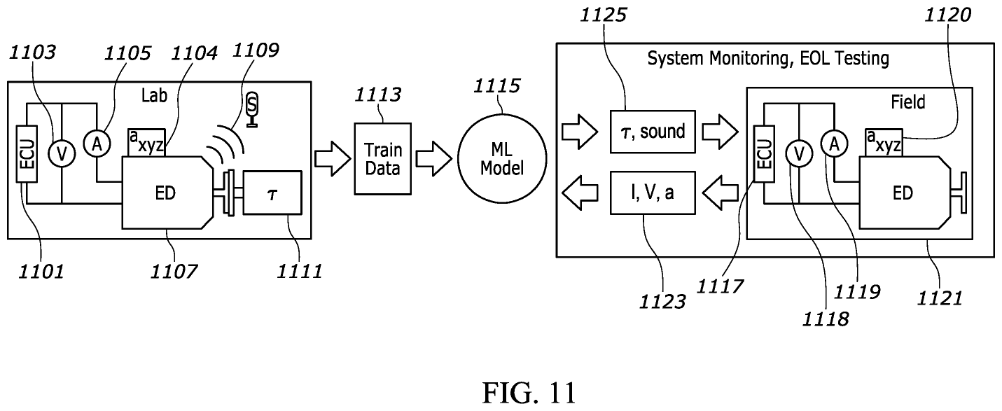

FIG. 11 discloses a chart of a system monitoring end of line testing as related to various sensor data to output a prediction, which may include a torque prediction or sound prediction. The system may include a machine learning model 1115. The machine learning model 1115 may be a deep neural network. The deep neural network (U-Net or a transformer) receives a set of sensor signals from sensors installed on an electric drive. The electrical device 1107 may be any type of device that includes a processor or ECU 1101, a motor, actuator, electrical drive, propulsion system, etc. The electrical device 1107 may include a component that outputs torque 1111 to a component. A sensor may be connected to that component to establish a torque reading. The electrical device 1107 may include sensors utilized to obtain readings of various characteristics in a certain environment, such as a laboratory setting. The sensors may be any type of sensor, such as a speed sensor, accelerometer 1109, voltage sensor (e.g., input voltage sensor) 1103, current sensor (e.g., input current sensor) 1105, torque sensor, etc. Signals can have the form of time series, spectrogram, order spectrogram, or other. The model performs signal-to-signal translation to predict the target sensor signals, such as torque, sound, or accelerometer data (if not included in the input). The target signal is predicted in the same format as the input. For example, if the input is in the form of a spectrogram, a spectrogram of the same dimensionality may be predicted. Once the prediction is made, it can be used in the appropriate analysis approaches the same way a target sensor data would be used, such as an NVH analysis, resonance detection, human perception analysis of the sound, fault detection, etc.

In the testing environment, current information, voltage information, sound information, and torque information may be collected to generated training data 1113. The training data 1113 may be sent to the trained machine learning model. In one scenario, the vibrational information may be accelerometer data. The real-time vibrational information may include accelerometer data that includes x-axis, y-axis, and z-axis information. The real-time information/data may be sent to the machine learning model in the form of either time series, spectrogram, or order spectrogram. The form of the input that is fed into the model may be the same as output of the model. For example, if a spectrogram is utilized as the input of the model, a spectrogram of the same dimensionality is predicted. Thus, the model may utilize a combination of various input readings from sensors to predict a corresponding sound or torque associated with the electrical device.

Next, an electronic device 1121 may be utilized in a different environment, such as a factory environment or end-of-line testing environment, etc. The electrical device 1121 may include sensors that include current (e.g., input current) readings from a current sensor 1119, voltage (e.g., input voltage) from a voltage sensor 1118, and vibrational information from a vibrational sensor 1120 (e.g., accelerometer) or other type of data emitted from electrical drive, actuator, or similar component. For example, the vibrational information in the EOL setting may be real-time vibrational data. The environment may not allow accurate use of sound information to be obtained, thus only the vibrational information may suffice to obtain a prediction 1125. The prediction 1125 may include a predicted sound, predicted torque, or predicted accelerometer data (if not included in the input). Thus, the model 1115 may output a predicted signal 1125 based on a combination of the input 1123 collected from the various sensors. For example, the model 1115 may utilize only real-time current information and real-time voltage information as input 1123 to output a prediction 1125. The prediction 1125 may be an expected sound prediction associated with the components operating on the electrical device 1121 given the values associated with the machine. The prediction 1125 may also be an expected torque prediction associated with the components operating on the electrical device 1121 given the values associated with the machine.

The prediction 1125 may utilize any set of data available to produce the prediction. Thus, if a certain sensor fails or is not available, the reading may not be necessary to produce the prediction. The model may take any available data or information to output the prediction. Furthermore, certain readings may be more beneficial than others. For example, a voltage reading may not need any concurrent readings, however, a current reading may need another information (e.g., voltage information or vibrational information) to generate a prediction. In another example, a voltage reading and vibrational reading alone may be enough. In another example, a current reading may be secondary information to help develop the prediction or improve the prediction.

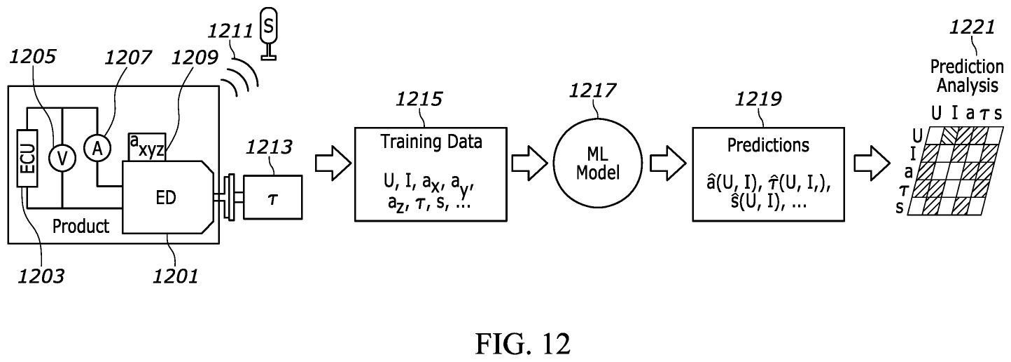

FIG. 12 discloses a flow chart associated with a prediction analysis model. The system may include a machine learning model 1217. The machine learning model 1217 may be a deep neural network. The deep neural network (U-Net or a transformer) receives a set of sensor signals from sensors in communication/connected to an electric drive 1201. The electrical device 1201 may be any type of device that includes a processor or ECU 1203, a motor, actuator, electrical drive, propulsion system, etc. The electrical device 1203 may include a component that outputs torque 1213 to a component. A sensor may be connected to that component to establish a torque reading. The electrical device 1201 may include sensors utilized to obtain readings of various characteristics in a certain environment, such as a laboratory setting. The sensors may be any type of sensor, such as a speed sensor, accelerometer 1209, voltage sensor (e.g., input voltage sensor) 1205, current sensor (e.g., input current sensor) 1207, torque sensor, etc.

A microphone may be utilized to pick-up sound 1211 from an electrical device 1201. A processor or ECU (e.g. electronic control unit) 1203 of the electrical device 1201 may be connected to and in communication with sensors reading input voltage 1205 and current of 1207 the device in operation. Furthermore, vibrational data 1209 may be collected from one or more sensors. The vibrational information 1209 may include accelerometer signal amongst three axis. For example, the accelerometer information of the x-axis, the accelerometer information of the y-axis, and accelerometer information of the z-axis may be utilized.

The proposed method may be intended for use during the analysis of complex physical systems, such as multi-component manufactured products. The quantities relationship between which needs to be investigated may be chosen. For example, the vibrations of the electric motor operating window lifters in a car and the sound inside the cabin may be a certain example. Secondly, the chosen quantities are measured in the appropriate setting, i.e. in the way that allows for the hypothesized relationship between measured quantities to be determined. In the above example, that would imply recording both the accelerometer and the microphone data at the same time in the same vehicle. A machine learning model 1217 may be utilized and fed the training data 1215. The training data 1215 may include voltage signal, current signal, accelerometer signal, torque signal, microphone signal, etc. The machine learning model 1217 may be a neural network that is trained to predict one of the quantities using the other, e.g. a signal-to-signal model that takes the accelerometer time series as an input and predicts sound time series.

And finally, the performance of the network may be analyzed to determine the presence and/or absence of the relationship and its properties. Thus, the prediction analysis 1221 may be utilized to grade the network and associated predictions. For example, the prediction error can be analyzed in the time domain to estimate the mutual information between motor vibrations and the sound inside the cabin, and in the frequency domain to determine which sound frequencies arise from motor vibrations. For the latter, a Fourier transform may be applied to both the predicted and the recorded signal to obtain the frequency information and the error may be calculated between the resulting Fourier coefficients. The prediction analysis 1211 may be in the form of a heat map, score, or any other type of output. The prediction analysis, in one illustrative embodiment, may analyze a predictions accuracy given its source information or input information. For example, a prediction analysis may indicate a performance of predicting vibrational information (e.g. accelerometer data) given only an input of voltage and current.

In one example, the system may compare a sound prediction to a recorded sound signal. The sound prediction may have been derived based on the accelerometer signal and the torque signal. The sound prediction may then be compared to the recorded sound signal to indicate a score or a color-coding that may be utilized in a heat map. In another example, the prediction may be accelerometer signal prediction utilizing the voltage signal and current signal. The accelerometer prediction (e.g., vibrational signal)

For reference, the term V/U: may indicate Voltmeter/voltage signal. The term A/I may indicated an Ammeter/current signal. The term τ may indicate a torque signal or another vibrational signal. The term s may indicate a microphone signal or a sound signal.

The processes, methods, or algorithms disclosed herein can be deliverable to/implemented by a processing device, controller, or computer, which can include any existing programmable electronic control unit or dedicated electronic control unit. Similarly, the processes, methods, or algorithms can be stored as data and instructions executable by a controller or computer in many forms including, but not limited to, information permanently stored on non-writable storage media such as ROM devices and information alterably stored on writeable storage media such as floppy disks, magnetic tapes, CDs, RAM devices, and other magnetic and optical media. The processes, methods, or algorithms can also be implemented in a software executable object. Alternatively, the processes, methods, or algorithms can be embodied in whole or in part using suitable hardware components, such as Application Specific Integrated Circuits (ASICs), Field-Programmable Gate Arrays (FPGAs), state machines, controllers or other hardware components or devices, or a combination of hardware, software and firmware components.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A computer-implemented method, comprising:
receiving a combination of two or more recorded signals indicating current information, voltage information, vibrational information, and sound information associated with a test device;
generating a training data set utilizing at least current information, voltage information, vibrational information, and sound information, wherein the training data set is sent to a machine learning model;
in response to meeting a convergence threshold of the machine learning model, outputting a trained machine learning model;
outputting a prediction utilizing the trained machine learning model and at least one recorded signal from the combination, wherein the prediction indicates a predicted signal characteristic associated with one of the two or more signals associated with the test device;
comparing the prediction and one of the two or more signals associated with the test device to identify a prediction error associated with the test device; and
outputting a prediction analysis indicating information associated with at least the prediction error, wherein the prediction analysis includes information indicative of a relationship between (i) the two or more recorded signals indicating current information, voltage information, vibrational information, and sound information and (ii) one or more of a sound, torque, or vibration emitted or absent from the test device in operation.

2. The computer-implemented method of claim 1, wherein the method includes applying a Fourier transform to both the prediction and the recorded signal to obtain frequency information; and
identifying the prediction error in response to calculating resulting Fourier coefficients from the frequency information.

3. The computer-implemented method of claim 1, wherein the prediction includes a sound prediction, vibrational prediction, or torque prediction.

4. The computer-implemented method of claim 1, wherein the prediction analysis is output in the form of a heat map.

5. The computer-implemented method of claim 1, wherein the method includes post-processing the prediction by applying a Fourier transform to the prediction.

6. The computer-implemented method of claim 1, wherein the trained machine learning model is a deep neural network.

7. The computer-implemented method of claim 6, wherein the deep neural network is a U-net or transformer network.

8. The computer-implemented method of claim 1, wherein the prediction analysis includes a score associated with the prediction.

9. The computer-implemented method of claim 1, wherein the prediction is associated with information not obtained in the recorded signal.

10. A computer-implemented method, comprising:
receiving a combination of two or more input signals indicating current information, voltage information, vibrational information, and sound information associated with a test device in a test environment;
generating a training data set utilizing at least current information, voltage information, vibrational information and sound information, wherein the training data set is sent to a machine learning model;
in response to meeting a convergence threshold of the machine learning model, outputting a trained machine learning model;
outputting a prediction utilizing the trained machine learning model and the combination, wherein the prediction indicates a signal characteristic prediction associated with the test device;
processing the prediction to obtain a post-processed prediction; and
in response to a comparison of the post-processed prediction and a prediction error, outputting a prediction analysis including information associated with the prediction, wherein the prediction analysis includes information indicative of a relationship between (i) one of the two or more recorded signals indicating current information, voltage information, vibrational information, and sound information and (ii) one or more of a sound, torque, or vibration emitted or absent from the test device in operation.

11. The computer-implemented method of claim 10, wherein the vibrational information includes accelerometer data including three-axis information associated with the test device.

12. The computer-implemented method of claim 10, wherein the prediction analysis includes information associated with a plurality of predictions compared to associated input signals.

13. The computer-implemented method of claim 10, wherein the prediction analysis includes information associated with a plurality of predictions.

14. The computer-implemented method of claim 10, wherein the prediction analysis includes information associated with a sound prediction, torque prediction, or accelerometer prediction.

15. The computer-implemented method of claim 10, wherein the combination includes input signals associated with a torque signal.

16. A system, comprising:
a processor in communication with one or more sensors, wherein the processor is programmed to:
receive a combination of two or more recorded signals indicating current information, voltage information, vibrational information, and sound information associated with a test device;
generate a training data set utilizing at least current information, voltage information, vibrational information and sound information, wherein the training data set is sent to a machine learning model;
in response to meeting a convergence threshold of the machine learning model, output a trained machine learning model;
output a prediction utilizing the trained machine learning model and at least one input information from the combination, wherein the prediction indicates a predicted signal characteristic associated one of the two or more recorded signals associated with the test device;
comparing the prediction to an associated recorded signal of the test device to identify a prediction error; and
output a prediction analysis indicating information associated with the prediction and the prediction error, wherein the prediction analysis includes information indicative of a relationship between (i) one of the two or more recorded signals indicating current information, voltage information, vibrational information, and sound information and (ii) one or more of a sound, torque, or vibration emitted or absent from the test device in operation.

17. The system of claim 16, wherein the prediction analysis is in the form of heat map identifying grading associated with predictions associated with relationships between the two or more signals.

18. The system of claim 16, wherein the prediction analysis includes a score associated with the prediction.

19. The system of claim 16, wherein comparing the prediction to the associated recorded signal of the test device to identify the prediction error includes comparing a sound prediction to a recorded sound signal associated with the test device.

20. The system of claim 16, wherein comparing the prediction to the associated recorded signal of the test device to identify the prediction error includes comparing a vibrational prediction to a recorded vibrational signal associated with the test device.
